(19) United States
(12) Patent Application Publication
(10) Pub. No.: US 2013/0207171 A1
(43) Pub. Date: Aug. 15, 2013

(54) SEMICONDUCTOR DEVICE HAVING CAPACITOR INCLUDING HIGH-K DIELECTRIC

(71) Applicant: Elpida Memory, Inc., (US)

(72) Inventor: Tomohiro UNO, Tokyo (JP)

(73) Assignee: ELPIDA MEMORY, INC., Tokyo (JP)

(21) Appl. No.: 13/733,554

(22) Filed: Jan. 3, 2013

(30) Foreign Application Priority Data
Jan. 10, 2012 (JP) 2012-002022

(51) Int. Cl. H01L 21/02; H01L 27/06

(52) U.S. Cl. CPC H01L 21/0228; H01L 27/0629
USPC 257/310; 438/785

(57) ABSTRACT

A first semiconductor device comprises a metal-oxide film over a substrate. The metal-oxide film is formed by an atomic layer deposition method including a treatment in a reducing gas atmosphere after forming oxidized metal. A second semiconductor device comprises a lower electrode having a cup shape over a substrate, a metal-oxide film covering the lower electrode, and an upper electrode covering the metal-oxide film. The metal-oxide film is formed by an atomic layer deposition method including a treatment in a reducing gas atmosphere after forming oxidized metal.

This application is based upon and claims the benefit of priority from Japanese Patent Application No. 2012-002022 filed on Jan. 10, 2012, the disclosure of which is incorporated herein in its entirety by reference.

### BACKGROUND OF THE INVENTION

1. Field of the Invention

The present invention relates to a semiconductor device having a capacitor including high-k dielectric.

2. Description of the Related Art

An ALD (atomic layer deposition) method has been known as a film formation method for forming an oxide film that excels in coverage. FIG. 1 shows process conditions in which an ALD method is carried out, and FIG. 2 is a flowchart of the ALD method. In the ALD method, a raw material layer is first formed on a substrate by flowing a metal-containing precursor (step 1), as shown in FIGS. 1 and 2. The metal-containing precursor is then purged (step 2). The raw material layer on the substrate is subsequently oxidized by flowing an oxygen-containing gas (step 3). The oxygen-containing gas is then purged (step 4). An oxide film formed of a monomolecular layer is thus formed on the substrate by carrying out one cycle of the steps 1 to 4 as described above. An oxide film having a desired film thickness is formed by increasing the number of cycles.

Since an ALD method, which forms a film formed of a monomolecular layer each time, it excels in coverage and is effective, in forming an oxide film in a minute hole. An ALD method is therefore used, for example, to form an oxide film for a capacitance insulating layer of a capacitor.

JP2007-201083A and JP2007-158222A disclose methods for forming an oxide film as a capacitance insulating layer based on an ALD method.

Further, US2005/0056219A1 discloses the forming a metal film by flowing a metal-containing precursor, a purge gas, an oxygen-containing gas, and a purge gas in this order.

To form a film based on an ALD method, a batch type vertical processing system is typically used. In the processing system, dozens of substrates are arranged for film formation in the vertical direction in a process chamber. The process chamber of the vertical processing system therefore has a large volume. Further, in an ALD method of related art, the film formation speed is slow because a monomolecular layer is formed in each cycle, and a large number of cycles therefore need to be carried out in order to form a desired film thickness. In view of the fact described above, the period of purging an oxygen-containing gas is set at a short period of about several tens of seconds to improve the productivity. It is therefore difficult to completely remove the oxygen-containing gas out of the process chamber or the oxygen-containing gas is left in the process chamber after the film formation cycles are completed, resulting in degradation in the quality of the formed film. In particular, portions of the film in the vicinity of the edges of the substrate react with the residual oxygen-containing gas, resulting in greater film thickness in the vicinity of the edges than the film thickness in the vicinity of the center of the substrate. As a result, the characteristics of a semiconductor device having the film are degraded, resulting in a decrease in yield.

On the other hand, in step 4, if the purge period is prolonged in order to facilitate purging the oxygen-containing gas out of the process chamber, the productivity is lowered. Further, even when the purge period is prolonged, it is difficult to completely remove the oxygen-containing gas out of the large-volume process chamber.

### SUMMARY OF THE INVENTION

In one embodiment, there is provided a semiconductor device comprising:

a metal-oxide film over a substrate,

wherein the metal-oxide film is formed by an atomic layer deposition method including a treatment in a reducing gas atmosphere after forming oxidized metal.

In another embodiment, there is provided a semiconductor device comprising:

a lower electrode having a cup shape over a substrate;

a metal-oxide film covering the lower electrode; and

an upper electrode covering the metal-oxide film,

wherein the metal-oxide film is formed by an atomic layer deposition method including a treatment in a reducing gas atmosphere after forming oxidized metal.

In another embodiment, there is provided a method of manufacturing a semiconductor device comprising:

providing a substrate in a process chamber of a batch type processing system;

(a) flowing a pulse of a metal-containing precursor in the process chamber;

(b) flowing a pulse of a purge gas in the process chamber;

(c) flowing a pulse of an oxygen-containing gas in the process chamber;

(d) flowing a pulse of a reducing gas in the process chamber; and

repeating a cycle formed of the flowing steps (a)-(d) at least once.

### BRIEF DESCRIPTION OF THE DRAWINGS

The above features and advantages of the present invention will be more apparent from the following description of certain preferred embodiments taken in conjunction with the accompanying drawings, in which:

FIG. 1 shows process conditions in related art;

FIG. 2 is a flowchart showing processes in related art;

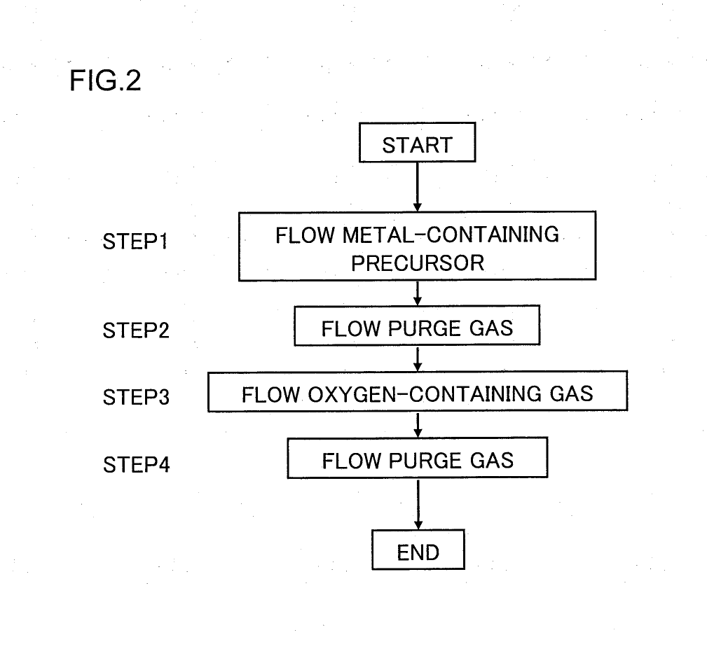

FIG. 3 is a cross-sectional view showing a vertical processing system;

FIG. 4 is a plan view showing the vertical processing system;

FIGS. 5A and 5B are flowcharts showing processes according to a first exemplary embodiment;

FIG. 6 shows process conditions according to the first exemplary embodiment;

FIG. 7 shows process conditions according to a second exemplary embodiment;

FIG. 8 shows process conditions according to a third exemplary embodiment;

FIG. 9 is a plan view showing a semiconductor device according to a fourth exemplary embodiment;

FIG. 10 is a cross-sectional view showing the semiconductor device according to the fourth exemplary embodiment;

FIG. 11 shows a method for manufacturing the semiconductor device according to the fourth exemplary embodiment;

FIG. 12 shows the method for manufacturing the semiconductor device according to the fourth exemplary embodiment;

FIG. 13 shows the method for manufacturing the semiconductor device according to the fourth exemplary embodiment;

FIG. 14 shows process conditions according to Example 2;

FIG. 15 shows change in film thickness of a zirconium-oxide film along the diameter of a substrate in Examples 1 to 3 and Comparative Example 1; and

FIG. 16 is a cross-sectional view showing a semiconductor device according to a fifth exemplary embodiment.

In the drawings, numerals have the following meanings: 1: vertical processing system, 2: process chamber, 3: exhaust pipe, 4: bottom plate, 5: heater, 6: stage, 7: substrate, 8, 8b, 8a, 8c, 8d: pipe, 9: flow port, 101: semiconductor substrate, 103: isolation region, 104: first interlayer insulating layer, 104A: bit line conductive plug, 105: gate electrode, 105a: gate oxide, 105b: sidewall, 105c: insulating layer, 106: bit line, 107: second interlayer insulating layer, 107A: capacitance conductive plug, 108: source/drain region, 109: substrate conductive plug, 111: third interlayer insulating layer, 112: fourth interlayer insulating layer, 112A: open hole, 113: lower electrode, 114: capacitance insulating layer, 115: upper electrode, 120: fifth interlayer insulating layer, 121: wiring layer, 122: surface protective film, 205a, 205b, 205c: substrate contact portion, Cap: capacitor element, K: active region, Tr1: MOS access transistor, W: word wiring line.

### DETAILED DESCRIPTION OF THE PREFERRED EMBODIMENTS

In an example of a method for manufacturing a semiconductor device according to the present invention, a metal-oxide film is formed on a substrate. The metal-oxide film is formed based on an ALD (atomic layer deposition) method in which after an oxidized metal is formed and it is treated in a reducing gas atmosphere. Specific steps in this ALD method are as follows:

providing a substrate in a process chamber of a batch type processing system;

flowing a pulse of a metal-containing precursor in the process chamber;

flowing a pulse of a purge gas in the process chamber;

flowing a pulse of an oxygen-containing gas in the process chamber;

flowing a pulse of a reducing gas in the process chamber; and

repeating the flowing processes at least one cycle.

In the flowing a pulse of each of the gases described above, the gas flow is terminated when this step is completed. Part of the oxygen-containing gas flowed in the flowing a pulse of an oxygen-containing gas is left as an unreacted oxygen-containing gas, which reacts with the reducing gas flowed in the flowing a pulse of a reducing gas. The oxygen-containing gas left in the process chamber of the batch type processing system is therefore converted into a non-oxidizing gas and hence disappear or does not adversely affect the film thickness uniformity of the metal-oxide film having been formed.

The method for manufacturing a semiconductor device may further include the purging the process chamber with a purge gas or the evacuating the process chamber after the flowing a pulse of a reducing gas. Carrying out such the additional step allows the following gases to be efficiently exhausted out of the process chamber: a reaction product gas produced by oxidizing the metal-containing precursor; a non-oxidizing gas produced by reducing the oxygen-containing gas; and an unreacted reducing gas. Exhausting the gases as described above can eliminate the problem of film thickness non-uniformity resulting from gas-phase reaction between the oxygen-containing gas left in the process chamber and the metal-containing precursor flowed in the following cycle and undesirable formation of an unintended deposition film on the substrate. As a result, a semiconductor device having excellent characteristics can be manufactured and the yield thereof can be improved.

The term “oxygen-containing gas” means a gas that oxidizes a metal-containing precursor (deprives metal-containing precursor of electrons). The term “reducing gas” means a gas that reduces an oxygen-containing gas (gives oxygen-containing gas electrons).

The steps of “flowing a pulse of a metal-containing precursor,” “flowing a pulse of a purge gas,” “flowing a pulse of an oxygen-containing gas,” and “flowing a pulse of a reducing gas” described above are carried out in this order, but the flowing a pulse of a reducing gas can be formed of a variety of sub-steps. Examples of the sub-steps that form the flowing a pulse of a reducing gas are the following sub-steps A to H:

Sub-Step A
(4-1) flowing a purge gas, and
(4-2) stopping flowing the purge gas and flowing a pulse of a reducing gas

Sub-Step B
(4-1) flowing a purge gas (first process step),
(4-2) stopping flowing the purge gas and flowing a pulse of a reducing gas (second process step), and
(4-3) stopping flowing the pulse of the reducing gas and flowing a purge gas (third process step)

Sub-Step C
(4-1) flowing a purge gas, and
(4-2) flowing a pulse of a reducing gas as well as the purge gas

Sub-Step D
(4-1) flowing a purge gas (first process step),
(4-2) flowing a pulse of a reducing gas as well as the purge gas (second process step), and
(4-3) stopping flowing the pulse of the reducing gas and flowing only the purge gas (third process step)

Sub-Step E
(4-1) evacuating the process chamber, and
(4-2) flowing a pulse of a reducing gas

Sub-Step F
(4-1) evacuating the process chamber,
(4-2) flowing a pulse of a reducing gas, and
(4-3) stopping flowing the pulse of the reducing gas and flowing a purge gas

Sub-Step G
(4-1) evacuating the process chamber,
(4-2) flowing a purge gas (first process step),
(4-3) stopping flowing the purge gas and flowing a pulse of a reducing gas (second process step)
(4-4) stopping flowing the pulse of the reducing gas and flowing a purge gas (third process step)

Sub-Step H
(4-1) evacuating the process chamber,
(4-2) flowing a purge gas (first process step),
(4-3) flowing a pulse of a reducing gas as well as the purge gas (second process step), and
(4-4) stopping flowing the pulse of the reducing gas and flowing only the purge gas (third process step)

Each of the sub-steps E to H has the evacuation step as the first step, which efficiently exhausts the oxygen-containing gas flowed in the flowing a pulse of an oxygen-containing gas and left in the process chamber.

In the sub-steps D and H, a gas flow rate of the purge gas may be the same in all of the process steps that include the first, the second and the third process steps.

When a substrate with a metal-oxide film formed thereon is produced by using the method for manufacturing a semiconductor device according to the present invention, {(maximum film thickness of substrate)−(minimum film thickness of substrate)}/(maximum film thickness of substrate) can be reduced to 0.07 or smaller.

The type of the metal-containing precursor may be changed after each cycle or every several cycles, to form a layered film formed of a plurality of films as the metal-oxide film. Specifically, the metal-oxide film can be a film selected from the group consisting of a zirconium-oxide film, a titanium-oxide film, a hafnium-oxide film, and a tantalum-oxide film.

The metal-containing precursor may be a precursor that contains the corresponding metal material. For example, to form a titanium-oxide film, titanium tetraisopropoxide (TTIP) is used as the metal-containing precursor. To form a hafnium-oxide film, tetrakis(ethylmethylamino)hafnium (TEMAH) is used as the metal-containing precursor. To form a tantalum-oxide film, tetradimethylamido tantalum (TDMAT) is used as the metal-containing precursor. To form a zirconium-oxide film as the metal-oxide film, it is possible to use a material containing any one of the compounds selected form the group consisting of Zr[N(CH₃)₂]₄, Zr[N(C₂H₅)(CH₃)]₄, Zr[N(C₂H₅)₂]₄, Zr(TMHD)₄, Zr(OiC₃H₇)₃(TMTD), and Zr(OtBu)₄ as the metal-containing precursor. From the viewpoint of film formation performance, Zr[N(C₂H₅)(CH₃)]₄ (TEMAZ: tetrakis(ethylmethylamino)zirconium) is preferably used. The metal-containing precursor described above corresponding to each of the films to be formed is a liquid and it is vaporized in a vaporizer, mixed with a carrier gas, such as nitrogen, and introduced into the process chamber.

The oxygen-containing gas is not limited to a specific one and can be any gas capable of oxidizing a metal-containing precursor, such as ozone gas and water vapor (H₂O). Ozone diluted with an inert gas, such as Ar, can alternatively used. Ozone is generated from oxygen as a raw material by using an ozone generator, carried by the oxygen, which is the raw material gas but also works as a carrier gas, and introduced into the process chamber. Oxygen is therefore simultaneously flowed in the flowing ozone, but what contributes to the reaction is ozone, which is highly reactive.

The reducing gas is not limited to a specific one and may be any gas capable of reducing an oxygen-containing gas. The reducing gas can, for example, be at least one type of gas selected from the group consisting of carbon monoxide (CO), methane (CH₄), and other hydrocarbon gases, and tri-methyl aluminum (TMA) and other organic metal compound gases. For example, when ozone (O₃) is used as the oxygen-containing gas and CO is used as the reducing gas, the two gases react with each other as follows:

3CO+O₃→3CO₂

As a result, the ozone is converted into a non-oxidizing gas and hence disappears.

When ozone (O₃) is used as the oxygen-containing gas and CH₄ is used as the reducing gas, the two gases react with each other as follows:

3CH₄+2O₃→3CO₂+2H₂

As a result, the ozone is converted into a non-oxidizing gas and hence disappears.

When ozone (O₃) is used as the oxygen-containing gas and TMA (Al(CH₃)₃) is used as the reducing gas, the two gases react with each other as follows:

2(Al(CH₃)₃)+O₃→Al₂O₃+3C₂H₆

As a result, the ozone is converted into a non-oxidizing gas and hence disappears.

When TMA is used as the reducing gas, Al₂O₃ (aluminum oxide) is produced but it has been experimentally ascertained that the produced Al₂O₃ does not adversely affect the uniformity of the film thickness. The reason for this is speculatively that the amount of flow of TMA is very small and that TMA, which is an organic metal gas made of Al(CH₃)₃, has a molecular weight smaller than those of the other metal-containing precursors and is hence diffused faster than the others in the process chamber. Further, for example, when a zirconium-oxide film is to be formed, and TMA is used as the reducing gas, the TMA contains an impurity in some cases, such as a trace amount of aluminum oxide that does not affect the film thickness uniformity, but an aluminum oxide is a very stable substance and functions to reduce the amount of leakage current flowing through the zirconium-oxide film. Therefore, aluminum oxide does not cause any inconvenience.

The purge gas is not limited to nitrogen and can alternatively be any other inert gas (such as Ar).

The temperature in each of the steps preferably ranges from 200 to 300° C. When the temperature in each of the steps of flowing a pulse of a metal-containing precursor and flowing a pulse of an oxygen-containing gas falls within the range described above, a metal-oxide film can be effectively formed. Further, when the temperature in the flowing a pulse of a reducing gas falls within the range described above, the oxygen-containing gas and the reducing gas are allowed to effectively react with each other.

The flow period and supply rate of each of the gases, the pressure in the process chamber, and other conditions may be so set that they are optimized in accordance with the processing system to be used. It is noted that the thickness of the metal-oxide film to be formed can be adjusted by adjusting the number of cycles as required.

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

In the present exemplary embodiment, a description will be made of a method for forming a zirconium-oxide film by using CO or CH₄ as the reducing gas based on the method for manufacturing a semiconductor device according to the present invention.

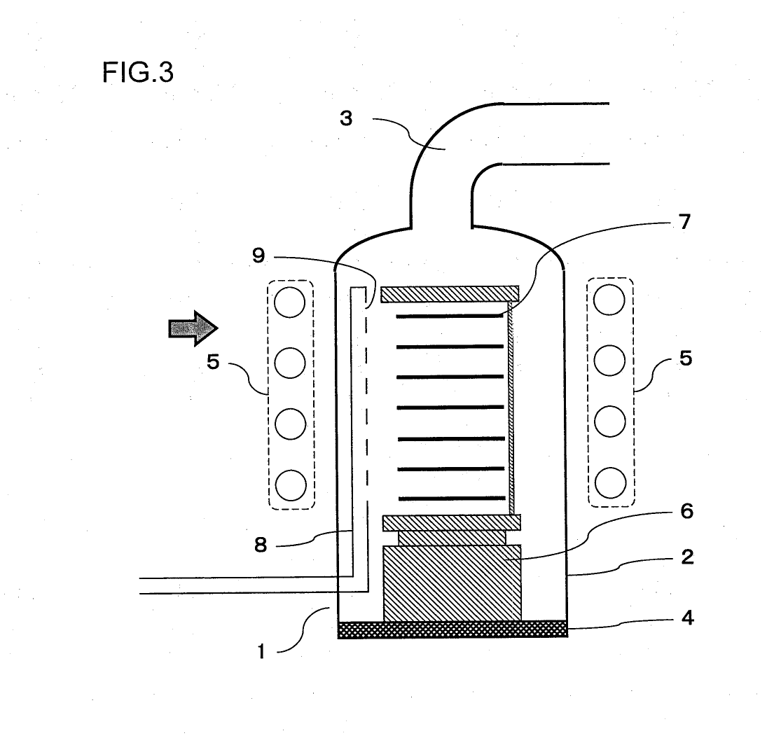

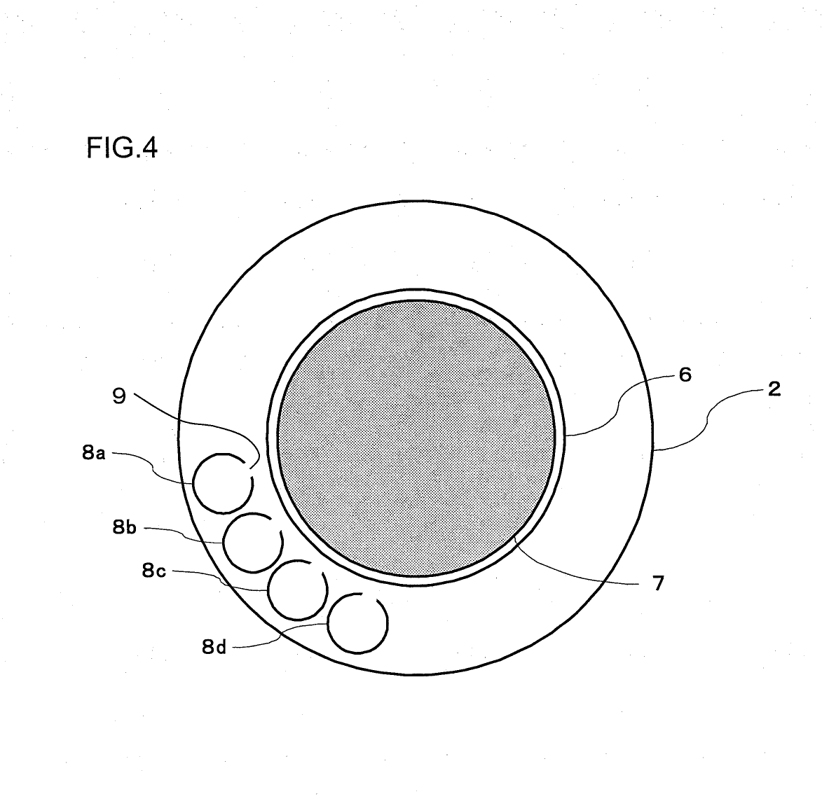

FIGS. 3 and 4 show a batch type processing system used in the present exemplary embodiment. FIG. 3 is a cross-sectional view, and FIG. 4 is a plan view. In batch type vertical processing system 1, a plurality of substrates 7 are placed on tubular stage 6 provided on bottom plate 4, as shown in FIGS. 3 and 4. Stage 6 and substrates 7 are equipped in process chamber 2 including bottom plate 4. A plurality of pipes 8 (8a, 8b, 8c, 8d) are disposed in the vicinity of the inner wall side surface of process chamber 2, and a metal-containing precursor, an oxygen-containing gas, a reducing gas, and a purge gas can be successively flowed through flow ports 9. The flow pipe through which the metal-containing precursor flows is provided with a vaporizer (not shown) that vaporizes a liquid raw material. Further, the flow pipe through which the oxygen-containing gas flows is provided with an ozone generator (not shown). Heater 5 is provided in the vicinity of the outer wall side surface of process chamber 2 and can heat process chamber 2. The gases flowed into process chamber 2 can be exhausted out of process chamber 2 through exhaust pipe 3. The processing system is configured in the same manner also in other exemplary embodiments.

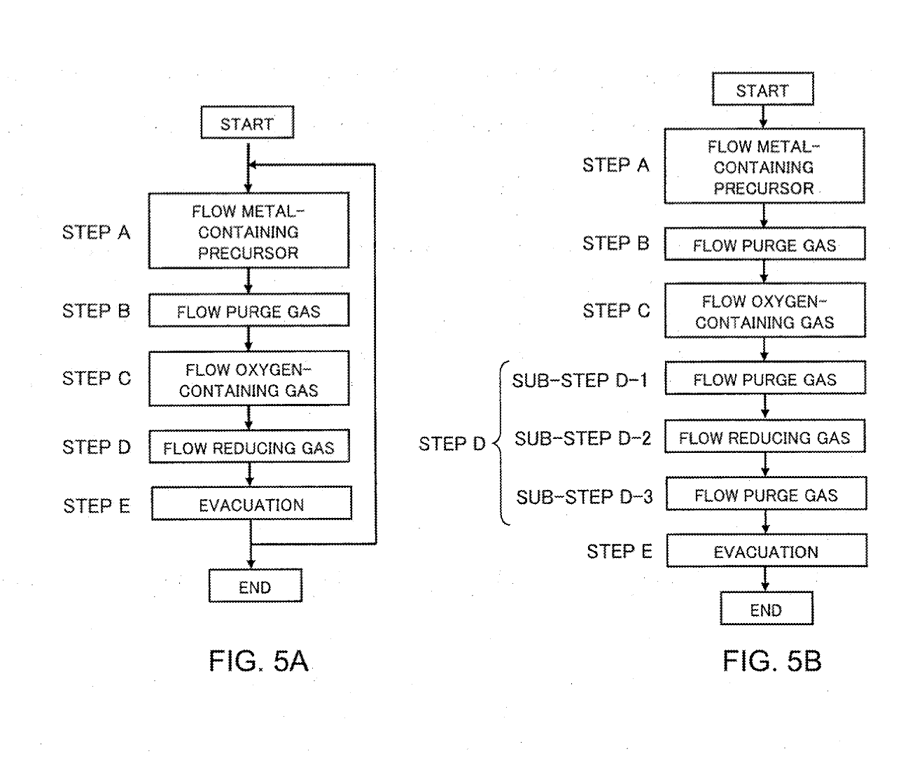

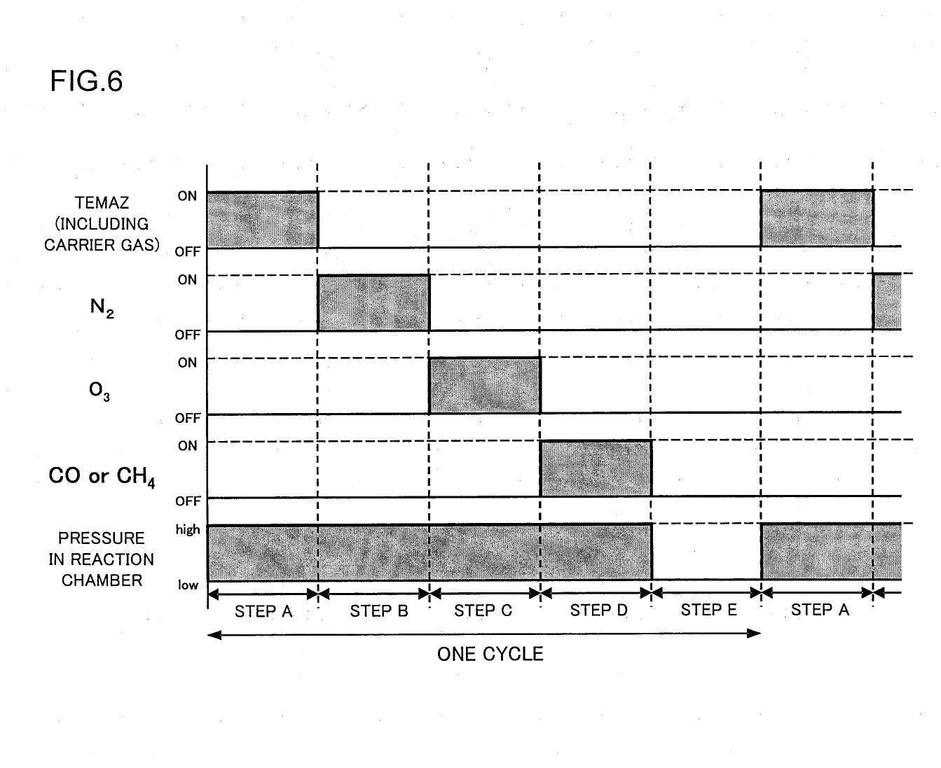

FIG. 5A is a process step flowchart showing a basic step cycle according to the present exemplary embodiment, and FIG. 6 shows process conditions according to the present exemplary embodiment. In the present exemplary embodiment, a unit cycle formed of the following steps (A1) to (A5) is repeated multiple times until the thickness of the zirconium-oxide film becomes a predetermined value.

(A1) TEMAZ gas (tetrakis(ethylmethylamino)zirconium gas; metal-containing precursor) is flowed (ON) into process chamber 2, where TEMAZ is chemically adsorbed onto each substrate 7 in a saturated adsorption state to form a monolayer metal-containing film (step A).

(A2) The flow of the TEMAZ gas is terminated (OFF), and nitrogen (N₂) gas (purge gas) is flowed (ON) into process chamber 2 to purge the TEMAZ gas not having been adsorbed in step (A1) but left in process chamber 2 out of process chamber 2 (step B).

(A3) The flow of the nitrogen gas is terminated (OFF), and ozone gas (O₃) (oxygen-containing gas) is flowed (ON) into process chamber 2. The TEMAZ gas adsorbed onto the substrate is thus oxidized to form a zirconium-oxide film (ZrO₂: metal-oxide film) formed of a monomolecular layer (step C).

(A4) The flow of the ozone gas is terminated (OFF), and carbon monoxide gas or methane gas (reducing gas) is flowed into process chamber 2. The ozone gas (O₃) left in process chamber 2 is thus allowed to react with the reducing gas and converted into a non-oxidizing gas (step D).

(A5) The flow of the reducing gas is terminated (OFF), and process chamber 2 is evacuated. Reaction products produced in the TEMAZ oxidation reaction and the non-oxidizing gas described above are thus effectively exhausted (step E).

### Second Exemplary Embodiment

In the present exemplary embodiment, a description will be made of a method for forming a zirconium-oxide film using TMA as the reducing gas based on an ALD method using the sub-step B described above in the flowing a pulse of a reducing gas.

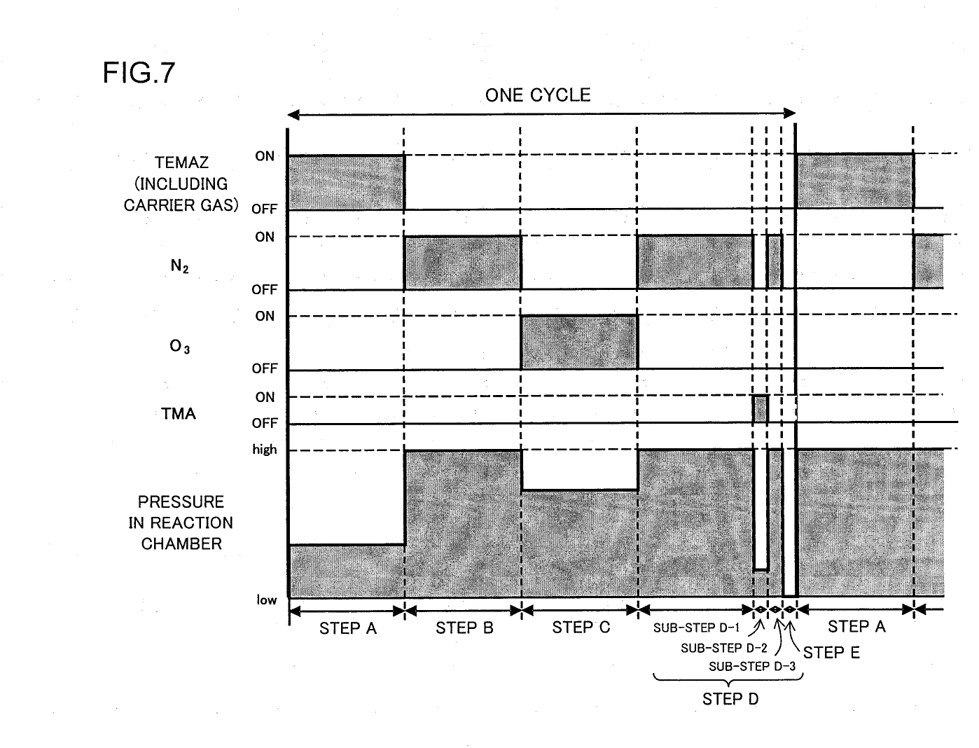

FIG. 5B is a process flowchart according to the present exemplary embodiment, and FIG. 7 shows process conditions according to the present exemplary embodiment. In the present exemplary embodiment, a unit cycle formed of the following steps (A1) to (A5) is repeated multiple times.

(A1) TEMAZ gas (tetrakis(ethylmethylamino)zirconium gas; metal-containing precursor) is flowed (ON) into process chamber 2, where TEMAZ is chemically adsorbed onto each substrate 7 in a saturated adsorption state to form a monolayer metal-containing film (step A).

(A2) The flow of the TEMAZ gas is terminated (OFF), and nitrogen (N₂) gas (purge gas) is flowed (ON) into process chamber 2 to purge the TEMAZ gas not having been adsorbed in step (A1) but left in process chamber 2 out of process chamber 2 (step B).

(A3) The flow of the nitrogen gas is terminated (OFF), and ozone gas (O₃) (oxygen-containing gas) is flowed (ON) into process chamber 2. TEMAZ adsorbed onto the substrate is thus oxidized to form a zirconium-oxide film (ZrO₂: metal-oxide film) formed of a monomolecular layer (step C).

(A4) The flow of the ozone gas is terminated (OFF), and nitrogen gas (purge gas) is flowed (ON) into process chamber 2 to purge the ozone gas (sub-step D-1).

The flow of the nitrogen gas is then terminated (OFF), and TMA gas (reducing gas) is flowed into process chamber 2. The ozone gas left in process chamber 2 is thus allowed to react with the reducing gas and converted into a non-oxidizing gas (sub-step D-2).

The flow of the TMA gas is then terminated (OFF), and nitrogen gas (purge gas) is flowed (ON) into process chamber 2 to purge reaction product gases produced in the TEMAZ oxidation reaction, the non-oxidizing gas described above, and other reaction products (sub-step D-3).

(A5) The flow of the nitrogen gas is terminated (OFF), and process chamber 2 is evacuated (step E).

In the present exemplary embodiment, the flow of the nitrogen gas is terminated in sub-step (D-2). As a result, in sub-step (D-2), the concentration of the reducing gas in process chamber 2 increases, and the oxygen-containing gas and the reducing gas effectively react with each other, whereby the unreacted oxygen-containing gas left in process chamber 2 can be converted into a non-oxidizing gas and hence disappears. Further, in sub-step (D-3), since the flow rate of the nitrogen gas is brought back to the level in sub-step (D-1), the oxygen-containing gas left in process chamber 2 as well as reaction product gases and the reducing gas (when left in process chamber 2) can be effectively exhausted out of process chamber 2. As a result, it is to possible to prevent the degradation in uniformity of the zirconium-oxide film over the surface of the substrate due to the residual oxygen-containing gas more effectively.

### Third Exemplary Embodiment

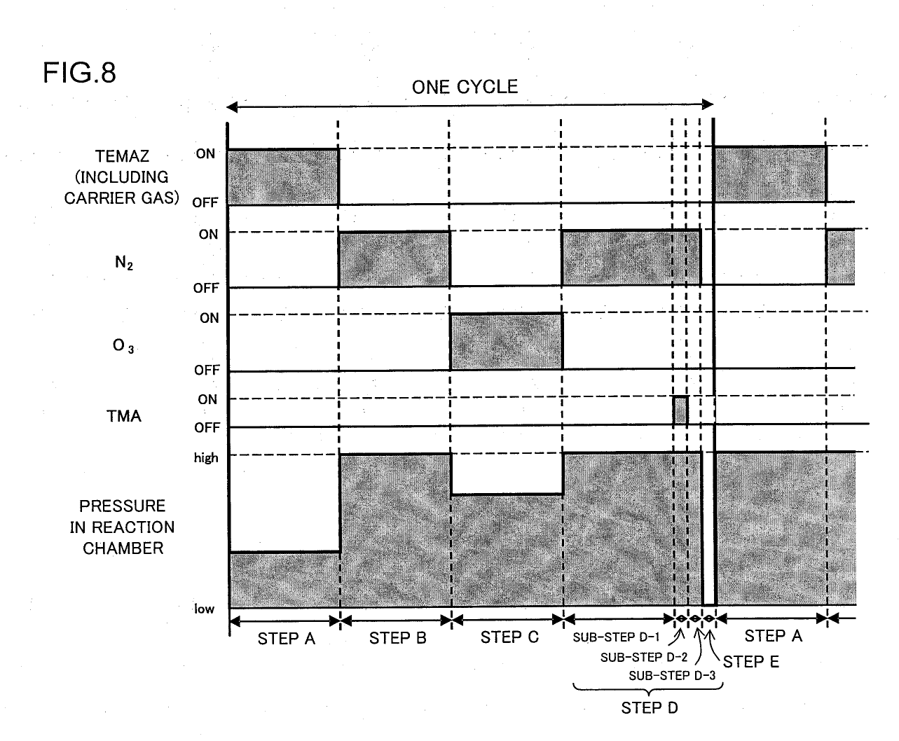

The present exemplary embodiment differs from the second exemplary embodiment in that the flow rate of the nitrogen gas (purge gas) in sub-step (D-2) in the second exemplary embodiment is not changed but remains the same as the flow rate in sub-step (D-1). The sub-step in the present exemplary embodiment corresponds to the sub-step D described above. FIG. 8 shows process conditions according to the present exemplary embodiment. In the present exemplary embodiment, the flow rate of the nitrogen gas is fixed through the sub-steps (D-1) to (D-3), as shown in FIG. 8. It is therefore not necessary to carry out the control for increasing or decreasing the flow rate of the nitrogen gas, whereby the process control can be simplified. As a result, the production cost can be reduced.

### Fourth Exemplary Embodiment

A specific example to which the present invention is applied will be described with reference to a case where the metal-oxide film is used as a capacitance insulating layer of a capacitor element that forms a memory cell of a DRAM (dynamic random access memory) device.

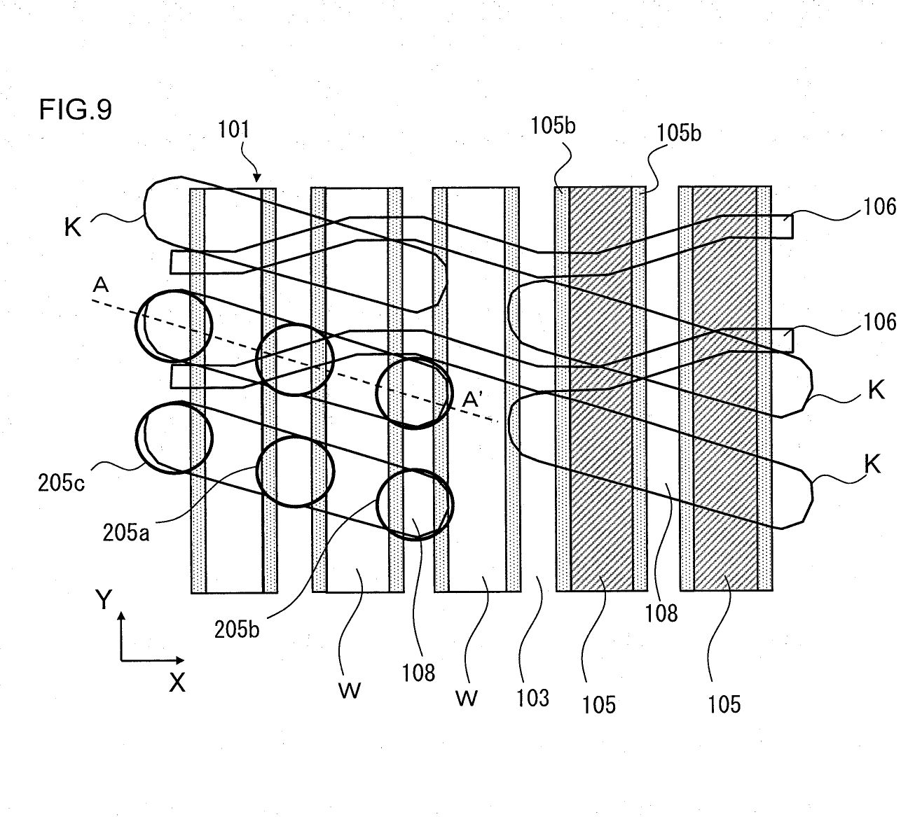

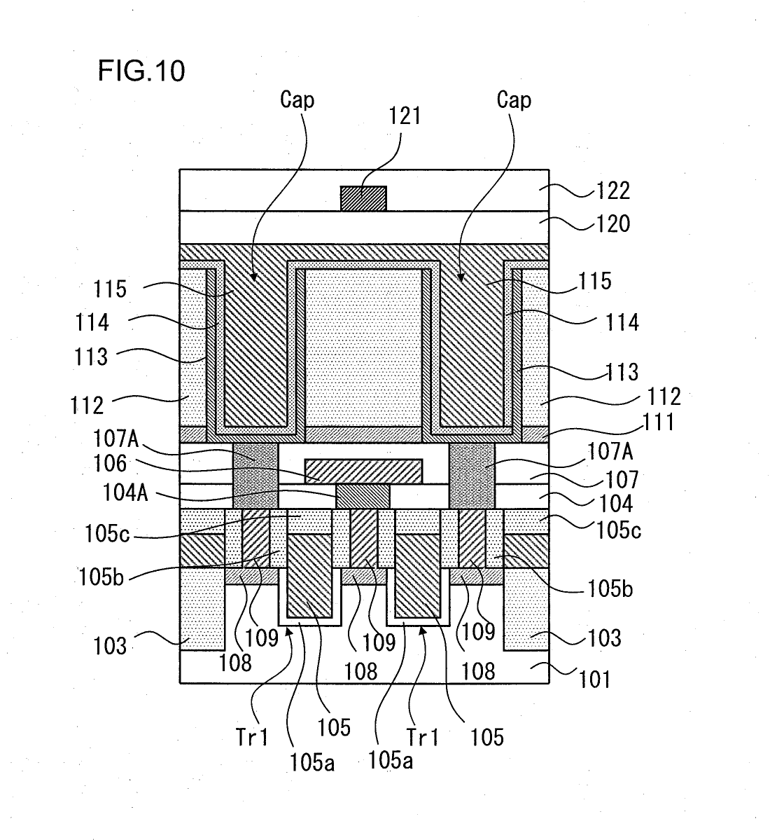

FIG. 9 is a conceptual diagram showing the layout of a memory cell portion in a plan view in a DRAM device as a semiconductor device to which the present invention is applied. The right portion of FIG. 9 is a transparent cross-sectional view in a reference plane that cuts gate electrodes 105 and sidewalls 105b, which form word wiring lines W, which will be described later. Capacitor elements are omitted in FIG. 9 for ease of illustration and shown only in the cross-sectional view of FIG. 10.

FIG. 10 is a schematic cross-sectional view of the memory cell portion (FIG. 9) taken along the line A-A′. It is noted that FIGS. 9 and 10 are presented to describe the configuration of the semiconductor device, and the size, dimension, and other attributes of each portion shown in FIGS. 9 and 10 differ from those of an actual semiconductor device.

The memory cell portion is generally formed of MOS access transistors Tr1 for memory cells and capacitor elements Cap connected to MOS access transistors Tr1 via a plurality of conductive plugs, as shown in FIG. 10.

In FIGS. 9 and 10, semiconductor substrate 101 is made of silicon (Si) containing a P-type impurity at a predetermined concentration. Isolation region 103 is formed in semiconductor substrate 101. Isolation region 103 is formed in the portion other than active regions K by burying a silicon oxide film (SiO₂) or any other suitable insulating layer in a surface of semiconductor substrate 101 in an STI (shallow trench isolation) process, and isolation region 103 insulatively isolates adjacent active regions K from each other. The present exemplary embodiment shows a case where the present invention is applied to a cell structure in which a 2-bit memory cell is disposed in one active region K.

In the present exemplary embodiment, a plurality of elongated strip-shaped active regions K are arranged in an orderly manner at predetermined intervals but inclined downward and rightward, as shown in the plan-view structure in FIG. 9 or arranged in accordance with what is typically called a 6F2 memory cell layout.

An impurity diffusion layer is formed in each of two end portions and a central portion of each of the active regions K and functions as a source/drain region of MOS access transistor Tr1. The positions of substrate contact portions 205a, 205b, and 205c are defined so that they are disposed immediately above the source/drain regions (impurity diffusion layers).

Bit wiring line 106 having a zigzag shape (curved shape) and extending in the horizontal (X) direction in FIG. 9 is disposed in a plurality of positions at predetermined intervals in the vertical (Y) direction in FIG. 9. Word wiring line W having a linear shape and extending in the vertical (Y) direction in FIG. 9 is disposed in a plurality of positions at predetermined intervals in the horizontal (X) direction in FIG. 9. Each word wiring line W includes gate electrode 105 shown in FIG. 10 disposed in a portion where the word wiring line intersects each active region K. In the present exemplary embodiment, MOS access transistor Tr1 includes groove-shaped gate electrode 105. Groove-shaped gate electrode 105 is formed of a gate electrode that covers an inner surface of a trench extending downwardly from a surface of semiconductor substrate 101 through gate oxide 105a. As shown in the cross-sectional structure in FIG. 10, impurity diffusion layers 108, each of which works as a source/drain region, are formed in separate positions in each of active regions K separated by isolation region 103, which partitions semiconductor substrate 101, and groove-shaped gate electrode 105 is formed between impurity diffusion layers 108.

Gate electrode 105 is formed of a multilayer film including a polycrystalline silicon film and a metal film and protrudes upward from semiconductor substrate 101, and the polycrystalline silicon film can be formed by introducing an impurity, such as phosphorous, in a CVD-based film formation process. The metal film for the gate electrode can be made of a refractory metal, such as tungsten (W), a tungsten nitride (WN), and a tungsten silicide (WSi).

Further, gate oxide 105a is formed between gate electrode 105 and semiconductor substrate 101, as shown in FIG. 10. Sidewall 105b, which is formed of an insulating layer such as a silicon nitride (Si₃N₄) is formed on each sidewall of gate electrode 105. Insulating layer 105c such as a silicon nitride is further formed on gate electrode 105 and protects the upper surface thereof.

Impurity diffusion layers 108 are formed, for example, by introducing an N-type impurity, such as phosphorous, into semiconductor substrate 101. Substrate conductive plugs 109 are formed so that they are in contact with impurity diffusion layers 108. Substrate conductive plugs 109 are disposed in the positions of substrate contact portions 205c, 205a, and 205b shown in FIG. 9 and made, for example, of phosphorous-containing polycrystalline silicon. The width of each substrate conductive plug 109 in the horizontal (X) direction is defined by sidewalls 105b provided on adjacent gate wiring lines W in accordance with a self-aligned structure.

First interlayer insulating layer 104 is formed so that it covers insulating layers 105c on gate electrodes 105 and substrate conductive plugs 109, and bit line conductive plug 104A is formed so that it passes through first interlayer insulating layer 104, as shown in FIG. 10. Bit line conductive plug 104A is located in the position of substrate contact portion 205a and electrically connected to corresponding substrate conductive plug 109. Bit line conductive plug 104A is formed by depositing tungsten (W) or any other suitable material on a barrier film (TiN/Ti) formed of a layered film made of titanium (Ti) and a titanium nitride (TiN).

Bit wiring line 106 is formed so that it is connected to bit line conductive plug 104A. Bit wiring line 106 is formed of a layered film of a tungsten nitride (WN) and tungsten (W).

Second interlayer insulating layer (insulating layer) 107 is formed so that it covers bit wiring line 106. Capacitance conductive plugs 107A are formed so that they pass through first interlayer insulating layer 104 and second interlayer insulating layer 107 and are connected to corresponding substrate conductive plugs 109. Capacitance conductive plugs 107A are located in the positions of substrate contact portions 205b and 205c.

Third interlayer insulating layer (etching stopper) 111 made of a silicon nitride and fourth interlayer insulating layer 112 formed of a silicon oxide film are formed on second interlayer insulating layer 107. Capacitor elements Cap are formed so that they pass through third interlayer insulating layer 111 and fourth interlayer insulating layer 112 and are connected to capacitance conductive plugs 107A.

Each capacitor element Cap has capacitance insulating layer (metal-oxide film) 114 formed between lower electrode having a cup shape 113 and upper electrode 115 by using the method described in detail in the first exemplary embodiment. That is, capacitor element Cap has a structure in which lower electrode 113 made of a titanium nitride film and upper electrode 115 made of a titanium nitride film sandwich capacitance insulating layer 114 formed of a zirconium-oxide film. Lower electrode 113 includes a top portion and a bottom portion. Although not illustrated definitely, in FIG. 10, capacitance insulating layer (metal-oxide film) 114 at an inner surface of the bottom portion is thinner in thickness than capacitance insulating layer (metal-oxide film) 114 at the top portion.

Each lower electrode 113 is electrically connected to corresponding capacitance conductive plugs 107A. Third interlayer insulating layer (etching stopper) 111 surrounds an outer surface of the bottom portion of lower electrode having a cup shape 113. Capacitance insulating layer (metal-oxide film) 114 is at least in contact with a part of third interlayer insulating layer (etching stopper) 111. There are formed fifth interlayer insulating layer 120, which is made, for example, of a silicon oxide, upper-layer wiring layer 121, which is made, for example, of aluminum (Al) or copper (Cu), and surface protective film 122 on third interlayer insulating layer 111.

A predetermined potential is applied to upper electrode 115 of each capacitor element Cap, which functions as a portion of a DRAM device that stores information based on determination of whether or not charge is held by the capacitor element Cap.

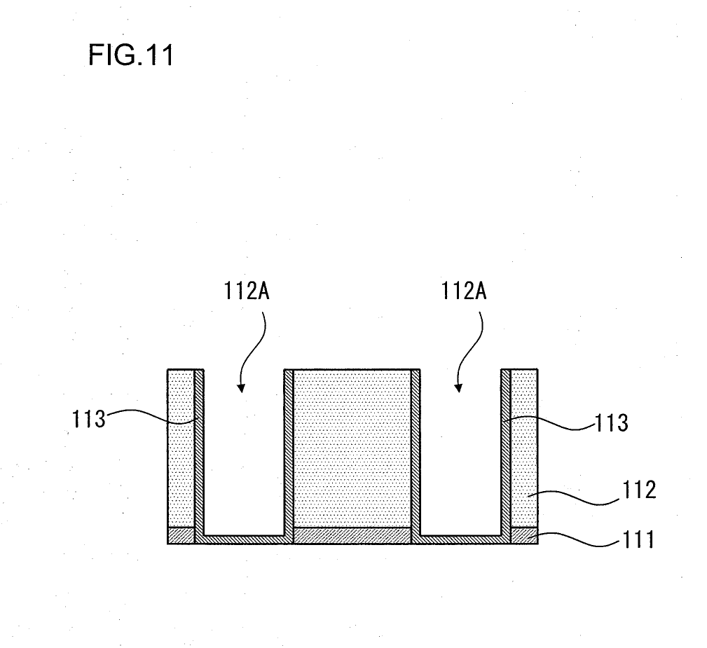

A specific method for forming capacitor elements Cap will next be described. FIGS. 11 to 13 are cross-sectional views showing only portions above third interlayer insulating layer 111. After third interlayer insulating layer 111 and fourth interlayer insulating layer 112 are first deposited to predetermined film thicknesses, open holes 112A for forming the capacitor elements Cap are formed by using a photolithography technique, as shown in FIG. 11.

Lower electrode 113 is formed so that it is left only on the inner wall of each open hole 112A by using a dry etching or CMP (chemical mechanical polishing) technique. The lower electrode is made of a titanium nitride but may alternatively be formed of any other suitable metal film.

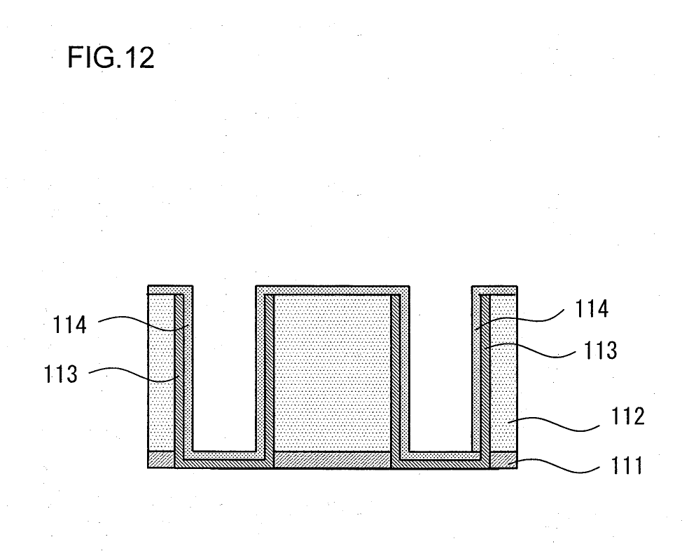

Capacitance insulating layer 114 formed of a zirconium-oxide film is then formed by using the ALD method described in the first exemplary embodiment, as shown in FIG. 12. To form capacitance insulating layer 114, the ALD method described in the first exemplary embodiment is not necessarily used, but it is possible to use any of those described in the second and third exemplary embodiments and ALD methods using a variety of sub-steps in the flowing a pulse of a reducing gas.

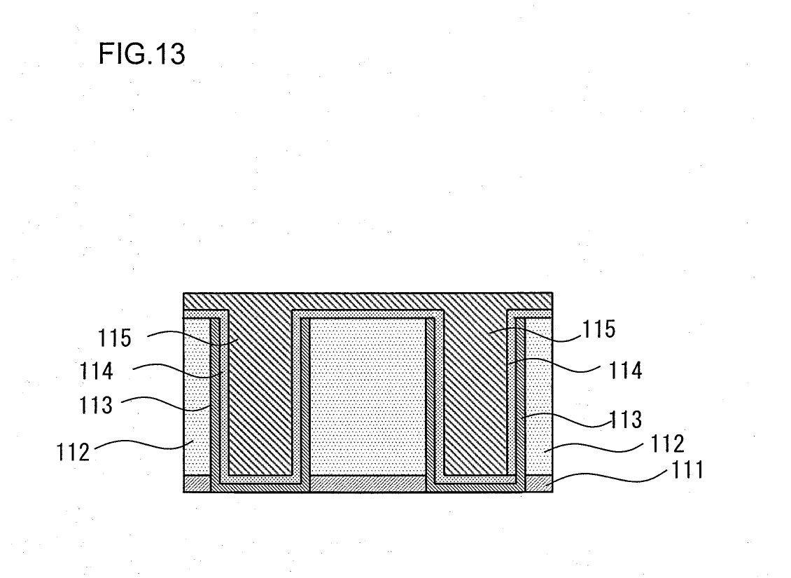

Upper electrodes 115 are then formed by depositing the same metal as the metal that forms the lower electrodes in such a way that the deposited metal covers the surface of capacitance insulating layer 114 and fills the open holes (112A), as shown in FIG. 13. Upper electrodes 115 may alternatively be made of a material different from the material of lower electrodes 113. Further, each of the lower and upper electrodes may be formed of a layered film of a plurality of metal films. Capacitor elements Cap are thus completed.

The present exemplary embodiment does not have the problem of non-uniformity of the thickness of the capacitance insulating layer due to the reaction between the unreacted oxygen-containing gas and the zirconium-oxide film having been formed. The charge holding characteristic of each capacitor element can therefore be improved, whereby capacitor element Cap having large electrostatic capacitance can be formed. As a result, a high-performance DRAM having an excellent data holding characteristic can be readily formed even when the capacitor elements are arranged in a highly integrated (miniaturized) manner.

### Fifth Exemplary Embodiment

In the fourth exemplary embodiment, there are cylinder-shaped capacitor elements Cap, in each of which capacitance insulating layer 114 and upper electrode 115 are formed on the inner wall surface of lower electrode 113, are formed. The present exemplary embodiment differs from the fourth exemplary embodiment in that crown-shaped capacitor elements Cap are formed. The structures of the other portions are the same as those in the fourth exemplary embodiment, and no description will be made of the structures other than that of capacitor elements Cap.

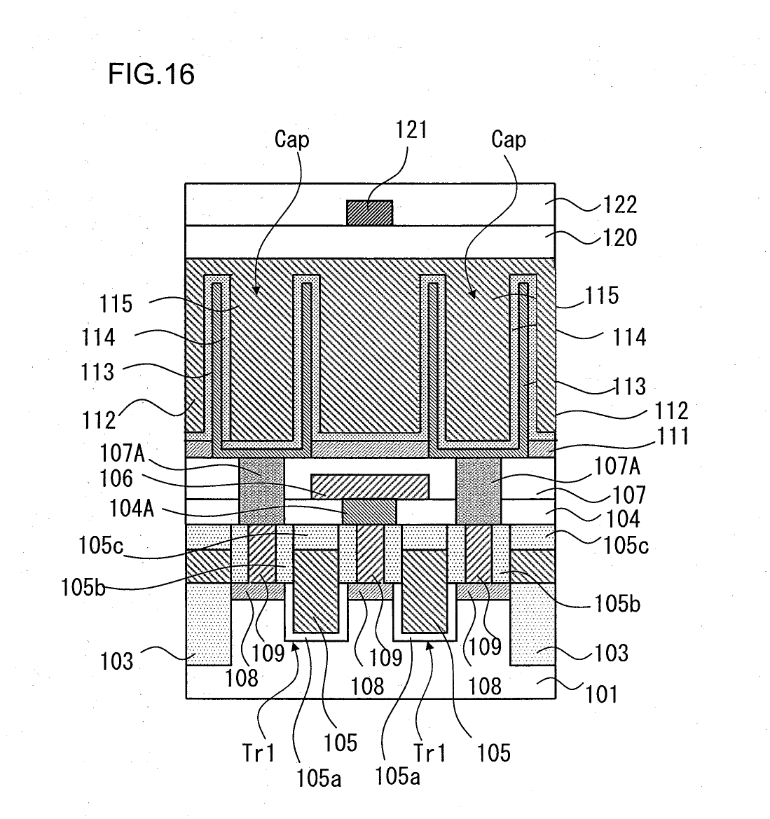

FIG. 16 is a cross-sectional view showing a semiconductor device according to the present exemplary embodiment and shows a cross section corresponding to the cross section shown in FIG. 10 in the fourth exemplary embodiment. In the semiconductor device according to the present exemplary embodiment, there are formed crown-shaped capacitor elements Cap, in each of which capacitance insulating layer 114 and upper electrode 115 are formed on the inner and outer wall surfaces of lower electrode 113, as shown in FIG. 16. In the forming capacitor elements Cap, after lower electrodes 113 are first formed in the step shown in FIG. 11 in the fourth exemplary embodiment, fourth interlayer insulating layer 112 is removed by a wet etching process using a hydrogen fluoride aqueous solution to expose the inner and outer wall surfaces of lower electrodes 113. Thereafter, according to the steps shown in FIGS. 12 and 13 in the fourth exemplary embodiment, capacitance insulating layer 114 and upper electrodes 115 are formed on the exposed inner and outer wall surfaces of lower electrodes 113. Capacitor elements Cap according to the present exemplary embodiment are thus completed.

In the present exemplary embodiment, since capacitance insulating layer 114 is formed by using the same method as that used in the fourth exemplary embodiment, the problem of non-uniformity of the thickness of capacitance insulating layer 114 will not occur, as in the fourth exemplary embodiment. As a result, a high-performance DRAM having an excellent data holding characteristic can be readily formed even when the capacitor elements are arranged in a highly integrated (miniaturized) manner.

### EXAMPLES

### Example 1

In the present example, a detailed description will be made of the first exemplary embodiment described above, in which a zirconium-oxide film is formed by using carbon monoxide or methane as the reducing gas based on the ALD method using the basic step cycle shown in FIG. 6.

Circular substrate 7 having a diameter of 300 mm was disposed in the process chamber of batch type processing system 2 shown in FIGS. 3 and 4. The temperature in process chamber 2 was maintained at 200° C. throughout the film formation stage. A unit cycle formed of the following steps (A1) to (A5) was then carried out 40 times in accordance with the procedure shown in FIG. 6, to form a zirconium-oxide film (metal-oxide film) having a thickness of 8.0 nm.

(A1) TEMAZ gas in a gaseous phase was flowed into process chamber 2 at a flow rate of 40 sccm for 60 seconds. Nitrogen gas flowed at a flow rate of 1 slm was used as a carrier gas. Process chamber 2 was controlled to operate in a high pressure state of 50 Pa. Under the conditions described above, TEMAZ was adsorbed onto the surface of substrate 7 in a saturated adsorption state to form a metal-containing film (step A).

(A2) The flow of the TEMAZ gas and the carrier gas was then terminated, and nitrogen gas was flowed as a purge gas at a flow rate of 10 slm for 60 seconds. The process chamber 2 was controlled to operate in a high pressure state of 200 Pa. The TEMAZ gas left in the process chamber 2 was thus exhausted (step B).

(A3) The flow of the purge gas was then terminated, and ozone was flowed as the oxygen-containing gas. The flow rate of oxygen gas, which was the raw material gas for producing ozone, was controlled to be 10 slm, and the concentration of ozone contained in the oxygen was controlled to be 200 g/Nm³. The process chamber 2 was controlled to operate in a high pressure state of 150 Pa. Under the conditions described above, TEMAZ adsorbed onto the surface of substrate 7 was oxidized to form a metal-oxide film formed of a zirconium-oxide (ZrO₂) film (step C).

(A4) The flow of the oxygen-containing gas was then terminated, and carbon monoxide (CO) was flowed as the reducing gas at a flow rate of 10 slm for 60 seconds. If methane (CH₄) is alternatively used as the reducing gas, the flow rate and the flow period thereof may set at the same values, as carbon monoxide. Under the conditions described above, the oxygen-containing gas left in the process chamber and in grooves and holes (open holes 112A in the fourth exemplary embodiment, for example) formed in the surface of substrate 7 was effectively converted into a non-oxidizing gas (step D).

(A5) The flow of the reducing gas was then terminated, and process chamber 2 was evacuated for 30 seconds. It was assumed that the evacuation period ranging from 5 to 30 seconds was long enough. The process chamber was controlled to operate in a “low” pressure state of 1 Pa. Under the conditions described above, the non-oxidizing gas left in the process chamber, reaction product gases produced in the TEMAZ oxidization reaction, and other gases were efficiently exhausted (step E).

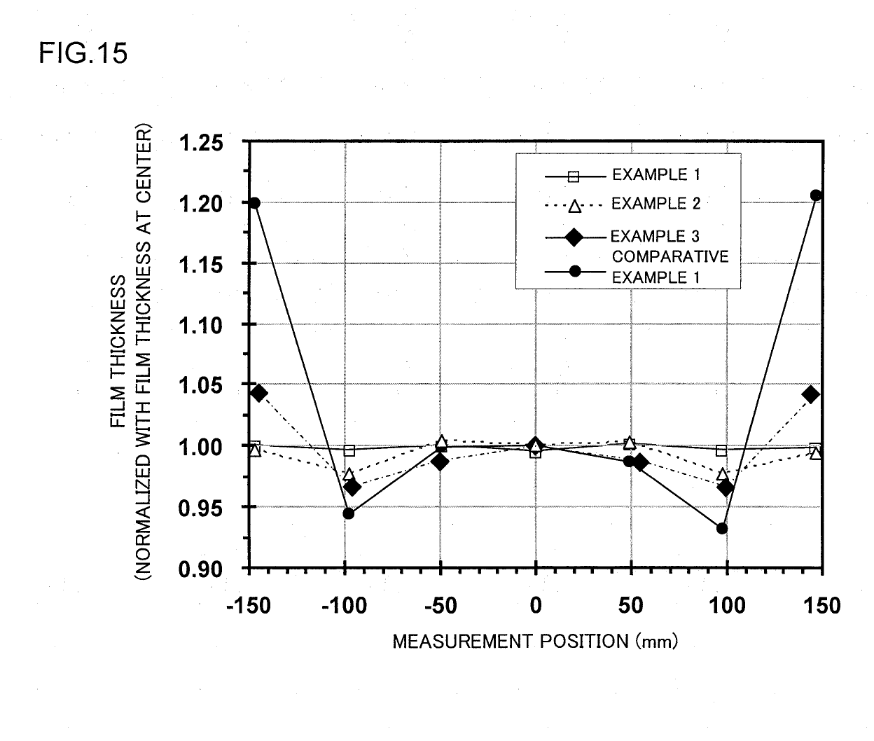

The measurement of change in film thickness along the diameter of the substrate was performed to the 300-mm-diameter substrate on which the zirconium-oxide film was formed as described above. Square marks in FIG. 15 show results of the measurement. FIG. 15 shows that {(maximum film thickness)−(minimum film thickness)}/(maximum film thickness) is about 0.005, indicating that variation in the thickness of the film of the substrate is small.

### Example 2

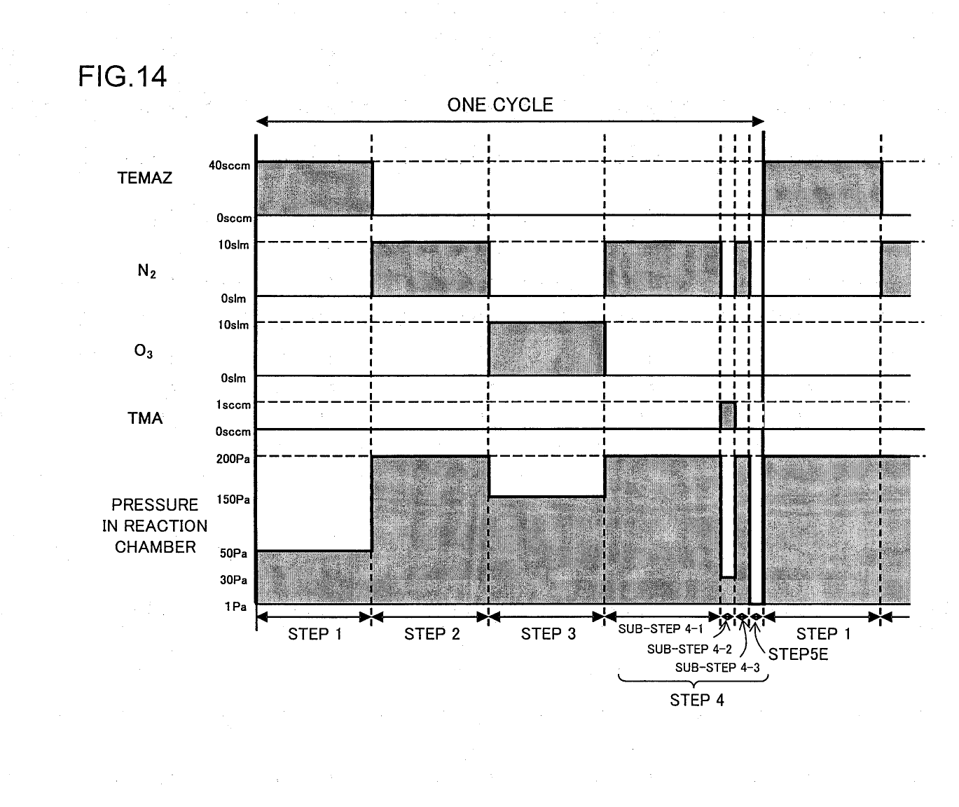

In the present example, a detailed description will be made of the second exemplary embodiment described above, in which a zirconium-oxide film is formed by using TMA as the reducing gas based on the ALD method using the sub-step B described above in the flowing a pulse of a reducing gas, with reference to FIG. 14.

Circular substrate 7 having a diameter of 300 mm was disposed in the process chamber of batch type processing system 2 shown in FIGS. 3 and 4. The temperature in the process chamber was maintained at 200° C. throughout the film formation stage. A cycle formed of the following steps (A1) to (A5) was then carried out 40 times in accordance with the procedure shown in FIG. 14 to form a zirconium-oxide film (metal-oxide film) having a thickness of 8.0 nm.

(A1) TEMAZ gas in a gaseous phase was flowed into process chamber 2 at a flow rate of 40 sccm for 60 seconds. Nitrogen gas flowed at a flow rate of 1 slm was used as a carrier gas for flowing the TEMAZ gas. The process chamber (reaction chamber) 2 was controlled to operate in a “high” pressure state of 50 Pa. Under the conditions described above, TEMAZ was adsorbed onto the surface of substrate 7 in a saturated adsorption state to form a first film (step A).

(A2) The flow of the TEMAZ gas and the carrier gas was then terminated, and nitrogen gas was flowed as a purge gas at a flow rate of 10 slm for 60 seconds. The process chamber 2 was controlled to operate in a “high” pressure state of 200 Pa. The TEMAZ gas left in the process chamber 2 was thus exhausted (step B).

(A3) The flow of the purge gas was then terminated, and ozone was flowed as the oxygen-containing gas. The flow rate of oxygen gas, which was the raw material gas for producing ozone, was controlled to be 10 slm, and the concentration of ozone contained in the oxygen was controlled to be 200 g/Nm³. The process chamber 2 was controlled to operate in a “high” pressure state of 150 Pa. Under the conditions described above, TEMAZ adsorbed onto the surface of substrate 7 was oxidized to form a metal-oxide film formed of a zirconium-oxide (ZrO₂) film (step C).

(A4) The flow of the ozone gas was then terminated, and nitrogen gas was flowed as a purge gas at a flow rate of 10 slm for 60 seconds. The process chamber 2 was controlled to operate in the “high” pressure state of 200 Pa. Under the conditions described above, residual ozone gas that did not contribute to the oxidization reaction and reaction products that was produced in the TEMAZ oxidization reaction were exhausted (sub-step D-1).

The flow of the nitrogen gas was then terminated, and TMA gas (reducing gas) was flowed at a flow rate of 1 sccm for 5 seconds. The pressure in the process chamber 2 was controlled to be 30 Pa. A flow rate of TMA ranging from 0.5 to 2 sccm was long enough. A flow period ranging from 3 to 10 seconds was long enough. Under the conditions described above, the oxygen-containing gas left in the process chamber 2 and in grooves and holes (open holes 112A in the fourth exemplary embodiment, for example) formed in the surface of substrate 7 was effectively converted into a non-oxidizing gas (sub-step D-2).

The flow of the TMA gas was then terminated, and nitrogen gas was flowed as a purge gas at a flow rate of 10 slm for 5 seconds. The process chamber was controlled to operate in the “high” pressure state of 200 Pa. Under the conditions described above, the non-oxidizing gas left in the process chamber 2 and in the grooves and holes formed in the surface of substrate 7 and reaction products described above were exhausted (sub-step D-3).

(A5) The flow of the nitrogen gas was then terminated, and process chamber 2 was evacuated for 5 seconds. An evacuation period ranging from 5 to 30 seconds was long enough. The process chamber 2 was controlled to operate in a “low” pressure state of 1 Pa. Under the conditions described above, the non-oxidizing gas left in the process chamber 2, reaction product gases produced in the TEMAZ oxidization reaction, and other gases were efficiently exhausted (step E).

The measurement of change in film thickness along the diameter of the substrate was performed to substrate 7 on which the zirconium-oxide film was formed as described above. Triangular marks in FIG. 15 show results of the measurement. The film thickness of the substrate is maximized at positions of −50 mm and 50 mm, whereas minimized at positions of −100 mm and 100 mm, as shown in FIG. 15. FIG. 15 also shows that {(maximum film thickness)−(minimum film thickness)}/(maximum film thickness) is about 0.025, indicating that variation in film thickness is small.

### Example 3

A zirconium-oxide film was formed in the same manner as in Example 1, except that the step of evacuation was omitted after the flowing a pulse of a reducing gas was carried out.

Thereafter, measurement of change in the film thickness along the diameter of the substrate was performed to the substrate on which the zirconium-oxide film was formed, as in Example 1. Filled rhombus marks in FIG. 15 show results of the measurement. The film thickness of the substrate according to Example 3 is maximized at positions of −150 mm and 150 mm, whereas minimized at a position of 100 mm, as shown in FIG. 15. FIG. 15 also shows that {(maximum film thickness)−(minimum film thickness)}/(maximum film thickness) is about 0.07, indicating that variation in film thickness decreases to about one-fourth as compared with Comparative Example 1 in related art, which will be described later. The above result shows that the film thickness uniformity is improved even when the step of evacuation is not carried out after the flowing a pulse of a reducing gas. It is, however, noted that even greater improvement is provided when the step of evacuation is carried out after the flowing a pulse of a reducing gas, as in Examples 1 and 2.

### Comparative Example 1

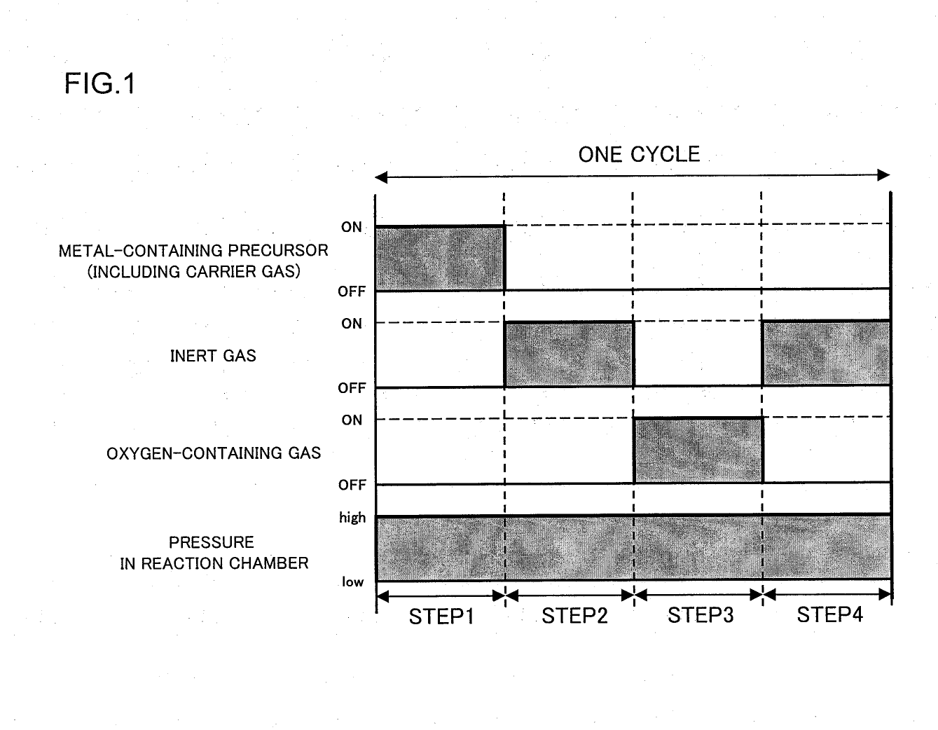

A zirconium-oxide film was formed based on Example 1 in which the flowing a pulse of a reducing gas and the evacuation was not carried out but instead only the flowing a purge gas was carried out, using the ALD method of related art shown in FIG. 1.

Thereafter, the measurement of change in the film thickness along the diameter of the substrate was performed to the substrate on which the zirconium-oxide film was formed, as in Example 1. Filled circular marks in FIG. 15 show results of the measurement. The film thickness of the substrate according to Comparative Example 1 is maximized at positions of −150 mm and 150 mm, whereas minimized at a position of 100 mm, as shown in FIG. 15. FIG. 15 also shows that {(maximum film thickness)−(minimum film thickness)}/(maximum film thickness) is about 0.27, indicating that variation in film thickness increases as compared with those in Examples 1 to 3.

As described above, according to the method for manufacturing a semiconductor device of the present invention, the in-substrate-plane uniformity of the thickness of a metal-oxide film formed on a substrate can be greatly improved. Further, even greater improvement can be provided by carrying out an additional step of evacuation after the flowing a pulse of a reducing gas.

It is apparent that the present invention is not limited to the above embodiments, but may be modified and changed without departing from the scope and spirit of the invention.

What is claimed is:

1. A semiconductor device comprising:
a metal-oxide film over a substrate,
wherein the metal-oxide film is formed by an atomic layer deposition method including a treatment in a reducing gas atmosphere after forming oxidized metal.

2. The semiconductor device according to claim 1,
wherein the metal-oxide film is at least one film selected from the group consisting of a zirconium-oxide film, a titanium-oxide film, a hafnium-oxide film and a tantalum-oxide film.

3. The semiconductor device according to claim 1, further comprising:
a lower electrode under the metal-oxide film; and
an upper electrode on the metal-oxide film,
wherein the metal-oxide film is a dielectric that is contained in a capacitor with the lower electrode and the upper electrode.

4. The semiconductor device according to claim 3, further comprising an access transistor,
wherein one of a source and a drain of the access transistor is electrically connected to the lower electrode, and
wherein the access transistor and the capacitor constitute a memory cell for DRAM.

5. A semiconductor device comprising:
a lower electrode having a cup shape over a substrate;
a metal-oxide film covering the lower electrode; and
an upper electrode covering the metal-oxide film,
wherein the metal-oxide film is formed by an atomic layer deposition method including a treatment in a reducing gas atmosphere after forming oxidized metal.

6. The semiconductor device according to claim 5,
wherein the metal-oxide film is at least one film selected from the group consisting of a zirconium-oxide film, a titanium-oxide film, a hafnium-oxide film and a tantalum-oxide film.

7. The semiconductor device according to claim 6,
wherein the metal-oxide film includes aluminum.

8. The semiconductor device according to claim 6,
wherein the lower electrode includes a top portion and a bottom portion, and
the metal-oxide film at an inner surface of the bottom portion is thinner in thickness than the metal-oxide film at the top portion.

9. The semiconductor device according to claim 8, further comprising:
an etching stopper surrounding an outer surface of the bottom portion of the lower electrode;
an insulating layer under the etching stopper; and
a conductive plug being electrically connected to the lower electrode in the insulating layer,
wherein the metal-oxide film is at least in contact with a part of the etching stopper.

10. The semiconductor device according to claim 9, further comprising:
an access transistor including a source and a drain, one of the source and the drain being electrically connected to the conductive plug; and
a capacitor including the lower electrode, the metal-oxide film and the upper electrode,
wherein the access transistor and the capacitor constitute a memory cell for DRAM.

11. The semiconductor device according to claim 10, further comprising:
a trench extending downwardly from a surface of the substrate; and
a gate electrode covering an inner surface of the trench through a gate oxide,
wherein the trench, the gate electrode and the gate oxide are included in the access transistor.

12. A method of manufacturing a semiconductor device comprising:
providing a substrate in a process chamber of a batch type processing system;
(a) flowing a pulse of a metal-containing precursor in the process chamber;
(b) flowing a pulse of a purge gas in the process chamber;
(c) flowing a pulse of an oxygen-containing gas in the process chamber;
(d) flowing a pulse of a reducing gas in the process chamber; and
repeating a cycle formed of the flowing steps (a)-(d) at least once.

13. The method of manufacturing a semiconductor device according to claim 12,
wherein the repeating the cycle comprises forming a metal-oxide film.

14. The method of manufacturing a semiconductor device according to claim 13,
wherein the reducing gas is at least one selected from the group consisting of tri-methyl aluminum, carbon monoxide and methane.

15. The method of manufacturing a semiconductor device according to claim 14,
wherein the repeating the cycle further comprises:
flowing the purge gas, as a first process step;
flowing the pulse of the reducing gas, as a second process step; and
flowing the purge gas, as a third process step.

16. The method of manufacturing a semiconductor device according to claim 15,
wherein in the second process step, the reducing gas and the purge gas are flowed.

17. The method of manufacturing a semiconductor device according to claim 15,
wherein a gas flow rate of the purge gas is the same in all of the process steps that includes the first, the second and the third process steps.

18. The method of manufacturing a semiconductor device according to claim 14,
wherein the metal-containing precursor is at least one selected from the group consisting of Zr(O-tBu)₄, Zr[N(CH₃)₂]₄, Zr[N(C₂H₅)(CH₃)]₄, Zr[N(C₂H₅)₂]₄, Zr(TMHD)₄, Zr(OiC₃H₇)₃(TMTD) and Zr(OtBu)₄, and
wherein the metal-oxide film is zirconium-oxide.

19. The method of manufacturing a semiconductor device according to claim 14,
wherein the metal-containing precursor is titanium tetraisopropoxide (TTIP), and
wherein the metal-oxide film is titanium-oxide.

20. The method of manufacturing a semiconductor device according to claim 14,
wherein the metal-containing precursor is tetrakis(ethylmethylamino)hafnium (TEMAH), and
wherein the metal-oxide film is hafnium-oxide.
